(19) United States
(12) Patent Application Publication
(10) Pub. No.: US 2023/0184818 A1
(43) Pub. Date: Jun. 15, 2023

(54) METHODS AND SYSTEMS FOR DETERMINING AN ELECTRICAL QUANTITY IN AN ELECTRICAL INSTALLATION

(71) Applicant: Schneider Electric Industries SAS, Rueil Malmaison (FR)

(72) Inventors: Stéphane Triomphe, Saint Martin d'Heres (FR); Bertrand Du Peloux De Saint Romain, Theys (FR); Roland Bohrer, La Sure en Chartreuse (FR)

(73) Assignee: Schneider Electric Industries SAS, Rueil Malmaison (FR)

(21) Appl. No.: 18/076,558

(22) Filed: Dec. 7, 2022

(30) Foreign Application Priority Data
Dec. 14, 2021 (FR) 2113473

(51) Int. Cl. G01R 19/25; G08C 17/02

(52) U.S. Cl. CPC G01R 19/2513; G08C 17/02

(57) ABSTRACT

A measurement system for an electrical installation includes at least one voltage measurement module and at least one current measurement module , which are coupled to the electrical installation, each measurement module including a sensor, a processor, a memory and a clock. A method for determining an electrical quantity in the installation allows the current measurement module to determine, for each synchronization signal received from the voltage measurement module, successive delay correction values on the basis of a main timestamp datum received from the voltage measurement module and a locally calculated timestamp datum. The successive current measurements taken by the current measurement module are timestamped by the module using the clock thereof, taking into account the delay correction values thus determined.

### TECHNICAL FIELD

The invention relates to a method for determining an electrical quantity in an electrical installation and to a corresponding system.

The invention relates more particularly to communicating sensors installed within electrical installations, such as electricity distribution networks.

### BACKGROUND

For example, wireless sensors capable of measuring electrical quantities, such as voltage or electrical current, are known.

The electrical quantities measured by the sensors may be used to monitor and supervise the electrical installation, but also to determine other electrical quantities that may be calculated on the basis of the measured electrical quantities.

For example, an electrical power value or a phase shift value may be calculated on the basis of the current and voltage values measured by the sensors.

The measurements are taken by the sensors repeatedly, by way of successive sampling over time. In many applications, it is necessary to know the precise moment at which an electrical quantity has been measured by a sensor, for example when data from multiple different sensors are combined.

One problem currently encountered in such sensor networks is that the sensors are not always correctly synchronized. Although each sensor is generally equipped with an internal clock, these clocks often undergo a drift over time, causing a loss of synchronization between the sensors.

There are systems in which a synchronization signal is sent by a main sensor to the other sensors so that these sensors are able to lock the clock thereof to a reference clock signal again.

The patent application US 2017/08379 A1 describes an example of synchronization, but it has the disadvantage of requiring a cabled link between the sensors. Such a solution cannot be used for wireless sensor networks.

Moreover, in the case of wireless sensors, repeatedly sending a synchronization message may burden the network used by the sensors to communicate with one another. Indeed, these sensors are often connected to one another by low-speed low-range radio communication means.

Furthermore, the electronic components used by the sensors to process the data introduce a processing time that may vary from one sensor to the other. This can cause errors, which vary from one sensor to the other.

Finally, the sensors are difficult to synchronize, and it is difficult to know with certainty whether the values that are supposed to have been measured at one and the same instant by all of the sensors have really been measured simultaneously. When the measured data are used to calculate other electrical quantities, such as electrical power, there is a risk that the calculation will be distorted by this loss of synchronization.

It is therefore desirable to be able to determine electrical quantities, in particular electrical quantities calculated on the basis of measurements taken by the sensors, easily and reliably.

### SUMMARY

To this end, one aspect of the invention relates to a method for determining an electrical quantity in an electrical installation, using a measurement system including at least one voltage measurement module and at least one current measurement module, which are coupled to the electrical installation, each of said measurement modules including a sensor, a processor, a memory and a clock, the method involving:
by way of the voltage measurement module:
   periodically measuring a voltage in the electrical installation,
   periodically sending a synchronization signal to at least one of the current measurement modules,
   sending to said current measurement module a message including at least one main timestamp datum indicating the instant at which the voltage measurement module has transmitted the synchronization signal, said instant being measured by the voltage measurement module using the clock thereof,
   sending to said current measurement module(s) a message including at least one measured voltage value,
by way of a current sensor measurement module:
   periodically measuring an electrical current in the electrical installation,
   on receiving the synchronization signal sent by the voltage measurement module, calculating, using the clock of said current measurement module, a local timestamp datum indicating the instant at which the current measurement module has received said synchronization signal,
   determining successive delay correction values on the basis of the main timestamp datum received and the local timestamp datum calculated for each synchronization signal received from the voltage measurement module, the successive current measurements taken by the current measurement module being timestamped by the current measurement module, using the clock thereof, taking into account the delay correction values thus determined,
by way of a processor, calculating at least one value of an electrical quantity on the basis of the successive current and voltage values from the measurement modules.

Owing to the invention, timestamping the current and voltage measurements and taking into account the intrinsic delay peculiar to the measurement chain of each sensor allow any delays after the measurement has been taken to be compensated for.

More particularly, instead of seeking to synchronize the current and voltage sensors so that they measure the signals at the same time, it is the voltage and current signals measured by the sensors that are synchronized virtually.

According to advantageous but not obligatory aspects, such a method may incorporate one or more of the following features, taken in isolation or based on any technically admissible combination:
the delay correction applied to the timestamp data associated with the measured current values is calculated according to the difference between the main timestamp datum received and the local timestamp datum calculated for one and the same synchronization signal;
the calculation of said electrical quantity includes first interpolating the current values for the instants corresponding to the instants for which the voltage values have been measured by the voltage measurement module, said interpolation being performed on the basis of the measured current values and the timestamp data associated with the measured current values;
a drift of the current measurement module is estimated on the basis of the ratio between, on the one hand, the time interval between two consecutive sendings of the synchronization signal by the voltage measurement module, said time interval being determined on the basis of the main timestamp data, and, on the other hand, the time interval between reception of two synchronization signals received consecutively by the current measurement module, said time interval being determined on the basis of the local timestamp data;
each voltage measurement by the voltage measurement module is timestamped by the voltage measurement module, the corresponding timestamp datum being sent by the voltage measurement module including, for each measured voltage value;
the timestamp data associated with the measured voltage values are automatically corrected, before being sent in said message, taking into account a time correction value previously stored in memory, said time correction value being from a preliminary calibration method;
the timestamp data associated with the measured current values are automatically corrected taking into account a time correction value previously stored in memory, said time correction value being from a preliminary calibration method;
to calculate the time correction value, the calibration method involves a method for determining a quantity as described hereinabove;
the measurement modules of the system are in communication via a wireless communication link, the message sent by the voltage measurement module being a radio message;
the measurement modules of the system are in communication via a wired communication link, such as a data bus;
the electrical quantity is calculated by an electronic processing circuit of at least one of the current measurement modules;
the calculated electrical quantity is an electrical power calculated on the basis of the current and voltage values measured by the measurement modules.

According to another aspect, the invention relates to a system for determining an electrical quantity in an electrical installation, said system including at least one voltage measurement module and at least one current measurement module, which are coupled to the electrical installation, each of said measurement modules including a sensor, a processor, a memory and a clock, the system being set up to implement a method for determining an electrical quantity, the method involving:
by way of the voltage measurement module:
   periodically measuring a voltage in the electrical installation,
   periodically sending a synchronization signal to at least one of the current measurement modules,
   sending to said current measurement module a message including at least one main timestamp datum indicating the instant at which the voltage measurement module has transmitted the synchronization signal, said instant being measured by the voltage measurement module using the clock thereof,
   sending to said current measurement module(s) a message including at least one measured voltage value,
by way of a current sensor measurement module:
   periodically measuring an electrical current in the electrical installation,
   on receiving the synchronization signal sent by the voltage measurement module, calculating, using the clock of said current measurement module, a local timestamp datum indicating the instant at which the current measurement module has received said synchronization signal,
   determining successive delay correction values on the basis of the main timestamp datum received and the local timestamp datum calculated for each synchronization signal received from the voltage measurement module, the successive current measurements taken by the current measurement module being timestamped by the current measurement module, using the clock thereof, taking into account the delay correction values thus determined,
by way of a processor, calculating at least one value of an electrical quantity on the basis of the successive current and voltage values from the measurement modules.

### BRIEF DESCRIPTION OF THE DRAWINGS

The invention will be better understood and other advantages thereof will become more clearly apparent in the light of the following description of one embodiment of a method and a system for determining an electrical quantity in an electrical installation, provided solely by way of example and with reference to the appended drawings, in which:

FIG. 1 is a schematic illustration of a system for measuring electrical quantities according to one implementation of the invention, said system comprising at least one voltage measurement module and a plurality of current measurement modules;

FIG. 2 schematically illustrates steps implemented by the voltage measurement module of FIG. 1;

FIG. 3 is a schematic illustration of a synchronization method implemented by the measurement modules of the system of FIG. 1 in order to determine an electrical quantity;

FIG. 4 schematically illustrates steps implemented by each current measurement module of FIG. 1;

FIG. 5 is a schematic illustration illustrating a delay for each measurement in the current and voltage sensors of the system of FIG. 1;

FIG. 6 is a schematic illustration of a calibration method implemented by the current sensors of the system of FIG. 1.

### DETAILED DESCRIPTION

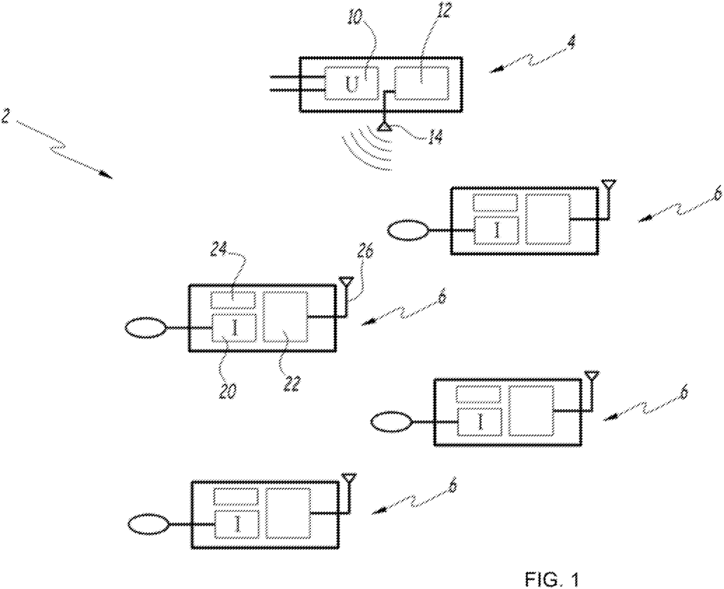

FIG. 1 schematically represents a measurement system 2 for measuring electrical quantities.

The system 2 is intended to be associated with an electrical installation, such as an electricity distribution installation, in order to measure electrical quantities within said electrical installation. Preferably, the electrical quantities measured include at least the electrical current and the voltage.

The system 2 is also set up to determine at least one electrical quantity on the basis of the measured quantities.

For example, said calculated electrical quantity is an electrical power (in particular an average electrical power, or an instantaneous electrical power, or the like) calculated on the basis of electrical current and voltage values measured by the sensors. As a variant, it could be a reactive power, or a phase shift, or a power factor of the electrical installation, or an energy value, or any other useful electrical quantity.

The system 2 includes at least one voltage measurement module 4 and at least one current measurement module 6.

In practice, the system 2 preferably includes a plurality of current measurement modules 6.

For example, the measurement modules 4 and 6 are distributed in the electrical installation.

In some variants, the system 2 could include multiple voltage measurement modules 4, but in these cases these modules will preferably function independently of one another, such that the description that will be provided below will be able to be transferred to these embodiments.

Preferably, the measurement modules 4 and 6 are connected sensors (or communicating sensors) that encompass information processing means and communication means. The measurement modules 4 and 6 may thus form a sensor network.

Each measurement module includes a measurement element, also called a sensor.

For example, for the voltage measurement module 4 to be intended to measure a voltage, the measurement element is a voltage sensor 10 (labelled “U” in the figure), for example a divider bridge, or a voltage transformer, or a capacitive sensor, or any other suitable sensor. For the current measurement module 6, the measurement element is a current sensor 20 (labelled “I” in the figure), such as a Rogowski coil, or a current transformer, or a Hall-effect sensor, or a shunt, or any other equivalent element.

Furthermore, each measurement module 4, 6 includes an electronic processing circuit including a processor, a memory, a clock and a communication interface.

Each measurement module 4, 6 preferably includes a casing accommodating all or some of the constituents of said measurement module. The measurement modules 4, 6 may also optionally include any means necessary to their operation, such as an electrical power supply or battery.

When the system 2 is operational, the measurement modules 4 and 6 are coupled to the installation. For example, the respective measurement elements of the modules 4, 6 are associated with electrical conductors of the electrical installation. The electrical installation is not shown in FIG. 1 for the sake of clarity of the drawings.

The sensors 4 and 6 may be distributed in the installation at different locations. For example, in many embodiments, the current sensors are associated with branches of the installation that are formed by electrical conductors, and the voltage sensor is connected upstream of the current sensors. In practice, preferably, the branches of the installation that have the current sensors installed on them share the same voltage source.

According to one illustrative and nonlimiting example, the electrical installation includes a primary electrical line and multiple secondary electrical lines tapped from the first electrical line. The primary line is for example connected to an electrical source, such as a generator or a distribution transformer, or to another electrical network. Each secondary line connects the primary line to a client entity, which includes an electrical load, for example. The modules 4, 6 are then associated with electrical conductors of the electrical installation, for example connected to or around the electrical conductors forming the main and secondary lines, in order to measure one or more electrical quantities relating to these electrical lines. In particular, in the case of a polyphase, in particular three-phase, installation, each primary or secondary electrical line may include multiple phase conductors, each associated with an electrical phase or possibly with a neutral line. Preferably, each measurement module 4, 6 is then set up to individually measure the current and voltage values associated with each of the phases on this electrical line.

Other setups are possible, however.

In many embodiments, in each measurement module 4 and 6, the data processing circuit is implemented by one or more electronic circuits.

The processor of each measurement module 4 and 6 is a microprocessor or a programmable microcontroller. The processor is coupled to a computer memory, or to any computer-readable data storage medium, that includes executable instructions and/or a software code provided for implementing, among other things, a method for determining one or more electrical quantities when these instructions are executed by the processor.

The use of the term “processor” in this description does not prevent, as a variant, at least some of the functions of each measurement module 4, 6 being performed by other electronic components, such as a signal processing processor (DSP), or a reprogrammable logic component (FPGA), or an application-specific integrated circuit (ASIC), or any equivalent element, or any combination of these elements.

The electronic processing circuit of each measurement module 4, 6 may also include components allowing the signals measured by the measurement element to be formatted and/or filtered before they are processed by the processor, such as an analogue-to-digital converter (ADC).

The clock of each measurement module 4, 6 includes an electronic oscillator, for example a crystal oscillator, such as a quartz oscillator. For example, the clock may be integrated in the processor of said measurement module 4, 6.

The communication interface of each measurement module 4, 6 allows data to be exchanged with other measurement modules 4, 6 and/or with one or more other elements, such as a data hub or telecommunications equipment, or computer equipment.

In preferred embodiments, the communication interface is a wireless interface, allowing a wireless communication link, for example a radio link, to be established. For example, the radio link may be a short-range radio link, such as a Bluetooth Low Energy (registered trademark) link, or equivalent. As a variant, it may be a low-speed long-range radio link, such as a ZigBee (registered trademark) link, or equivalent.

In other embodiments, the communication interface is set up to establish a wired communication link, for example using one or more cables, such as Ethernet cables or the like. The wired link may, for example, be a data bus.

In the example shown, the processing circuit and the communication interface of the first measurement module 4 bear the references “12” and “14”, respectively. The processing circuit, the memory and the communication interface of the second measurement module 6 bear the numerical references “22”, “24” and “26”, respectively.

Generally, each measurement module 4, 6 is set up to measure an electrical quantity such as voltage or current repeatedly over time, for example by sampling (measuring) said electrical quantity periodically using a fixed sampling frequency.

In practice, the voltage and the electrical current may be alternative quantities that change periodically over time, for example with a sinusoidal shape.

For example, the voltage measurement module 4 periodically measures a voltage using a first sampling frequency. Each current measurement module 6 periodically measures an electrical current using a second sampling frequency. The first sampling frequency and the second sampling frequency are higher than the frequency of the measured signal.

In many examples, the first sampling frequency is chosen to be equal to the second sampling frequency. This is not essential, however, and, as a variant, the first sampling frequency could be different from the second sampling frequency.

The system 2 is in particular set up to determine at least one electrical quantity, such as an electrical power, on the basis of the current and the voltage that are measured by the different measurement modules 4, 6. For example, the electrical power (for example an instantaneous value or an average value) may be calculated for different branches of the electrical installation.

This calculation is made on the basis of the current and voltage values sampled over time. For example, for each instant, a value of said quantity (such as power) is calculated on the basis of the current and voltage values sampled for this instant.

For this calculation, it is desirable for the current and voltage values used for calculating such an electrical quantity for any given instant to correspond to simultaneous or quasi-simultaneous instants.

For example, in this description, “quasi-simultaneously” is understood to mean that the measurements are taken for one and the same instant to within 0.1 microsecond (µs).

Advantageously, the method could be generalized to any synchronization and clock time adjustment mechanism provided by exchanging messages between the measurement modules 4 and 6 in order to timestamp the samples that meets the requirement of measurement precision.

In practice, said quantity (such as power) is calculated by a processor, for example by one of the current measurement modules, or by a dedicated computer device that is in communication with the measurement modules 4, 6.

Generally, the system 2 is set up (and programmed) to implement a method involving steps consisting of:
by way of the voltage measurement module 4:
   periodically measuring a voltage (U) in the electrical installation,
   periodically sending a synchronization signal (Top signal) to at least one of the current measurement modules 6,
   sending to said current measurement module(s) 6 a message including a main timestamp datum (TopMasterTime) indicating the instant at which the voltage measurement module has transmitted the synchronization signal, said instant being measured by the voltage measurement module using the clock thereof,
   sending to said current measurement module(s) 6 a message including at least one measured voltage value,
by way of a current measurement module 6:
   periodically measuring an electrical current in the electrical installation,
   on receiving the synchronization signal sent by the voltage measurement module 4, calculating, using the clock of said current measurement module 6, a local timestamp datum (TopLocalTime) indicating the instant at which the current measurement module 6 has received said synchronization signal,
   determining successive delay correction values on the basis of the main timestamp datum received (TopMasterTime) and the local timestamp datum calculated for each synchronization signal received from the voltage measurement module, the successive current measurements taken by the current measurement module being timestamped by the current measurement module 6, using the clock thereof, taking into account the delay correction values thus determined.

Next, by way of a processor, calculating at least one value of an electrical quantity on the basis of the successive current and voltage values from the measurement modules.

The current and voltage values measured independently by the voltage 4 and current 6 measurement modules are not in sync, because the respective clocks of these modules are independent.

However, as will be seen below, the calculation step introduces a correction that allows the measured current values to be re-synchronized with the measured voltage values a posteriori, in particular with the intention of realigning the current values (which are measured at discrete instants) on the same timescale as the measured voltage values.

For example, the missing current values for the instants at which the voltage values have been measured are interpolated in order to re-sample current values between measured data. The current and voltage values then appear to have been measured simultaneously, which allows said electrical quantity to be calculated with good precision. To put it another way, current values are calculated by interpolation between the values actually measured (sampled), in order to obtain current values that are in sync with the voltage values from the voltage measurement module 6.

Advantageously, as explained in more detail in the description that follows, timestamp data of the voltage values are measured by the voltage module, on the basis of the clock of the voltage module.

The voltage timestamp data correspond to the instant at which the voltage measurement has been taken, or to a proximate instant with as stable as possible an offset in time. Each timestamp datum is preferably sent by the voltage measurement module with the measured voltage value.

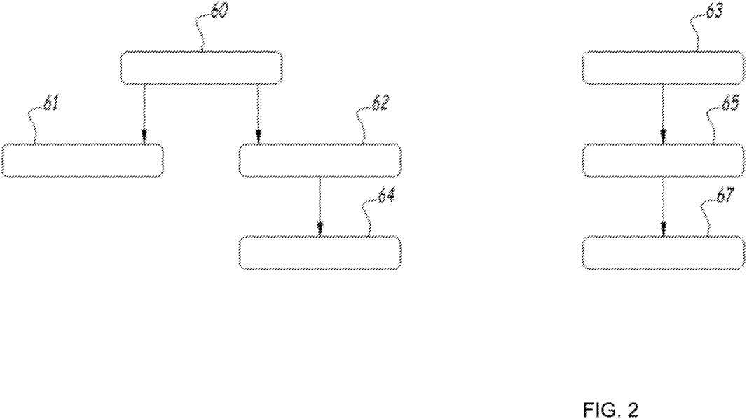

An example of a method of operation of the system 2 is now described with reference to FIGS. 2, 3 and 4. As a variant, the steps of the method that will be described could be performed in a different order. Some steps could be omitted. The example described does not prevent, in other embodiments, other steps from being implemented together and/or sequentially with the steps described.

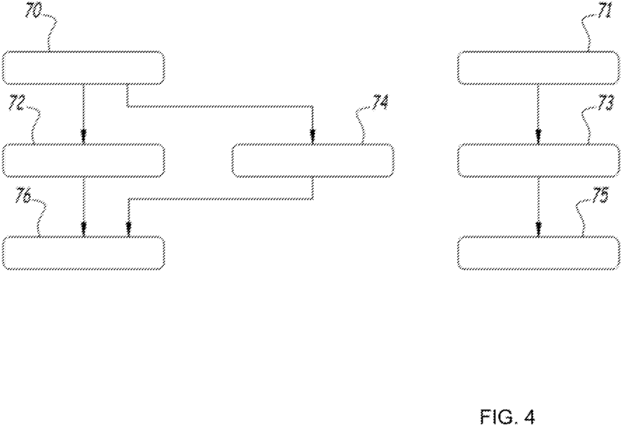

The diagram in FIG. 2 shows the steps implemented by at least one voltage measurement module 4. The diagram in FIG. 4 shows the steps implemented by a voltage measurement module 6.

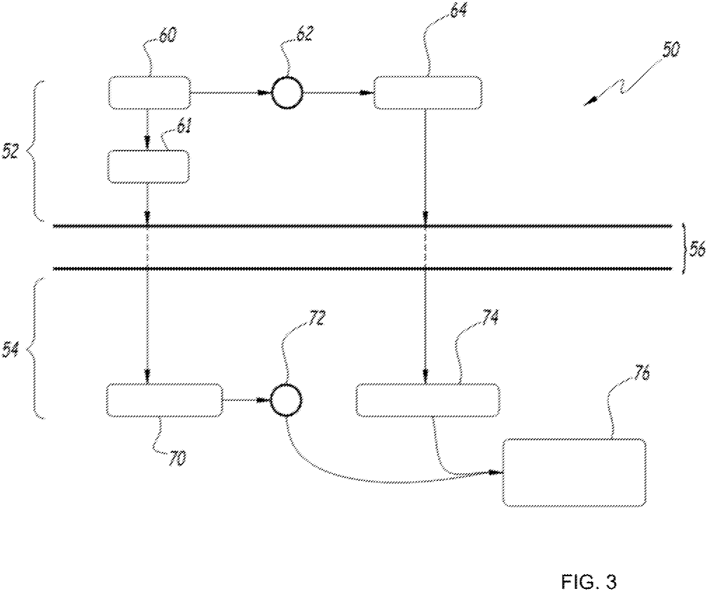

The diagram 50 in FIG. 3 shows steps implemented both by at least one voltage measurement module 4 (reference 52) and by one of the current measurement modules 6 (reference 54).

The steps illustrated in these figures are, for example, implemented by the respective processors of the voltage measurement module 4 and of the current measurement modules 6.

The method is described for one of the current measurement modules 6, but it is understood that in practice each of the current measurement modules 6 implements analogous steps, independently of the other current measurement modules 6.

The voltage measurement module 4 and each of the current measurement modules 6 are in communication using communication links 56 that may form a communication network. This communication is permitted by the communication interfaces 14 and 26 described hereinabove.

Initially, the voltage measurement module 4 and each of the current measurement modules 6 are installed in the electrical installation.

In practice, the steps of the method are repeated periodically during an operating phase of the system 2. However, to simplify the description, only one iteration of these steps is described in detail.

Moreover, in the diagram in FIG. 3, only the steps relating to management of time and of the synchronization are explained in detail, the steps relating to the current and voltage measurements not being explained in detail in this figure.

The method starts in step 60, in which the voltage measurement module 4 transmits a synchronization signal. For example, this synchronization signal marks the start of a periodically repeated cycle.

The synchronization signal is sent on the communication link 56 (step 61). In practice, it is the sending of this message on the communication link that serves as synchronization signal. In this case, steps 60 and 61 are combined.

The measurement module 4 then carries out timestamping, in step 62, using the clock of said measurement module. In doing this, the measurement module 4 determines a timestamp datum, referred to as the “main timestamp datum”, in order to date, in the time reference frame of the measurement module 4, the instant (Top time) at which the synchronization signal is transmitted.

In this description, the term timestamping is used to denote an operation consisting of measuring the instant at which an event seen by the measurement module occurs using the clock thereof, and then to associate this measured instant with the event in question.

For example, the timestamp data (the measured values of the instants) are associated with the measured values by being stored in memory in a list, or a table, or in any suitable data structure.

In other words, the main timestamp datum indicates the instant at which the voltage measurement module transmits the synchronization signal, this instant being measured by the voltage measurement module using the clock thereof, in the time reference frame thereof.

Next, the measurement module 4 sends, to at least one of the current measurement modules 6, a message including the main timestamp datum (step 64).

In parallel, in a step 63, the voltage measurement module 4 measures a voltage in the electrical installation, preferably periodically using the first sampling frequency. For example, the voltage measurement module 4 samples the voltage using the voltage sensor 10 thereof.

In doing this, in a step 65, the measurement module 4 determines a timestamp datum for each voltage measurement (for each sampling) in order to date the instant of the voltage measurement in the time reference frame of the voltage measurement module 4. In other words, each measured voltage value is timestamped by the measurement module 4 using the clock thereof.

Next, the measurement module 4 sends, to each of the corresponding current measurement modules 6, a message including the measured voltage value (step 67), preferably with the timestamp thereof.

In practice, in a preferred embodiment, by way of the voltage measurement module 4, the sending of the synchronization signal, of the main timestamp datum and of the measured voltage values is grouped into one and the same message. To put it another way, steps 61, 64 and 67 are combined.

For example, this message serves as synchronization signal and includes, stored in the body of the message, the measured voltage values and the main timestamp datum associated with the previous synchronization signal (that is to say the one that initiated the previous cycle).

However, in other embodiments, the voltage measurement module 4 could send the synchronization signal, the main timestamp datum and the measured voltage values in separate messages.

In other embodiments, the messages could be partially combined, for example as in FIG. 3, with, during each cycle, a first message for the synchronization signal and a second message to send the remainder of the data.

In many embodiments, the frequency at which the message is sent may be lower than the first sampling frequency and than the second sampling frequency. For example, the frequency at which the message is sent is at least ten times lower than the first sampling frequency and/or than the second sampling frequency. By way of example, each message sent by the voltage measurement module 4 includes a number of voltage (measurement value) samples of between twenty and one hundred, or even between thirty and fifty. If the measurement module is associated with multiple electrical conductors and includes as many voltage sensors, for example in a polyphase installation, then each message sent may include the values measured for these different conductors at the same instant

In the text below, the voltage measurement module 4 may be called the “main module”.

Moreover, as will be seen later, the main timestamp data contained in the messages sent by the voltage measurement module 4 are used subsequently to compensate for the delay variations and the drifts between the different measurement modules 4 and 6.

In a step 70, the current measurement module 6 receives the synchronization signal sent by the voltage measurement module 4. For example, this corresponds to reception of a message on the communication interface 56.

In practice, the synchronization signal is detectable by all of the current measurement modules 6. It may be detected with greater or lesser delay by the different current measurement modules 6, provided that this delay is fixed for each measurement.

On receiving the synchronization signal sent by the voltage measurement module 4, the current measurement module 6 measures (step 72), using the clock thereof, a local timestamp datum indicating the instant at which the current measurement module 6 has received said synchronization signal.

According to the possible embodiments, the instant of detection of reception of the synchronization signal may be taken as the moment from which the preamble of the message is received by the communication interface 56, or the moment from which the body of the message is received. Other examples are possible as a variant, so long as the method used is consistent and it produces the least possible variability in the processing period on reception of the message between successive measurement cycles.

More preferably, to limit such variability, the message is sent by the voltage measurement module 4 by limiting or even omitting all bidirectional communication between the respective communication interfaces 14 and 26 of the measurement modules 4 and 6 (for example by omitting bidirectional communication routines of “handshake” type or of “discovery” type).

Preferably, said message is sent by a broadcast method by the voltage measurement module 4.

More preferably, said message has a header of fixed length.

Next, in a step 74, the main timestamp data (previously generated by the module 4) contained in the received message are extracted. The main timestamp datum received from the voltage sensor 4 and associated with the sending of the synchronization signal is for example associated with the local timestamp datum calculated on reception of the synchronization signal.

In step 76, the current measurement module 6 automatically determines parameters that will allow estimation of the time offset between the local clock of the current measurement module 6 and the clock of the voltage measurement module 4. To put it another way, the current measurement module 6 determines parameters aimed at expressing the time measured locally by the clock thereof in the time reference frame corresponding to the voltage measurement module 4.

This allows in particular calculation of the drift of the measurement module 6 in relation to the measurement module 4.

This allows especially the current measurement module 6 to estimate the time reference frame of the main module 4 and to convert the timestamp of the current measurements in this estimated reference frame. Nevertheless, the estimation of the synchronization of the current and voltage samples includes an error that will be known or corrected only when the calibration method described below has been implemented.

In many embodiments, an offset between the modules 4 and 6 is calculated on the basis of the difference between the instants at which the message was sent. A drift of the current measurement module 6 is estimated on the basis of the ratio between the time interval between two successive sendings of the message by the voltage measurement module 4, as determined on the basis of the main timestamp data, and the time interval between the reception of two consecutive messages by the current measurement module 6.

In some examples, for each current measurement module 6, the period between two consecutive messages received may be deducted and used as information for determining this correction. This allows the instant of reception of said message to be dated in the time reference frame of the current measurement module 6.

Generally, the delay correction applied to the timestamp data associated with the measured current values is calculated according to the difference between the main timestamp datum received and the local timestamp datum calculated for one and the same synchronization signal.

For example, the measurement module 6 calculates the drift coefficient (termed “slope”) using the following formula:

$$S l o p e = \frac{M a s t e r T i m e B e t w e e n T o p s}{L o c a l T i m e B e t w e e n T o p s}$$

where: “MasterTimeBetweenTops” denotes the time interval between two consecutive sendings of the synchronization signal by the voltage measurement module 4, said time interval being determined on the basis of the main timestamp data contained in the successively sent messages, and where
“LocalTimeBetweenTops” denotes the time interval between the reception of two consecutive synchronization signals by the measurement module 6.

Preferably, the coefficient used for the later calculations is determined by calculating an average over multiple cycles (for example by taking the current average calculated on the basis of at least ten or fifty previous values).

Other methods of calculation are nevertheless possible as a variant.

For example, the measurement module 6 calculates the gap (termed “offset”) between the starting of the respective clocks of the two measurement modules 4 and 6 using the following formula:

$$O f f s e t = L a s t S y n c M a s t e r T i m e$$

where “LastSyncMasterTime” denotes the instant at which the message was sent by the voltage measurement module 4 (called “Top time” above), said instant being measured (timestamped) by the voltage measurement module 4 in the time reference frame thereof, this information being contained in the received message.

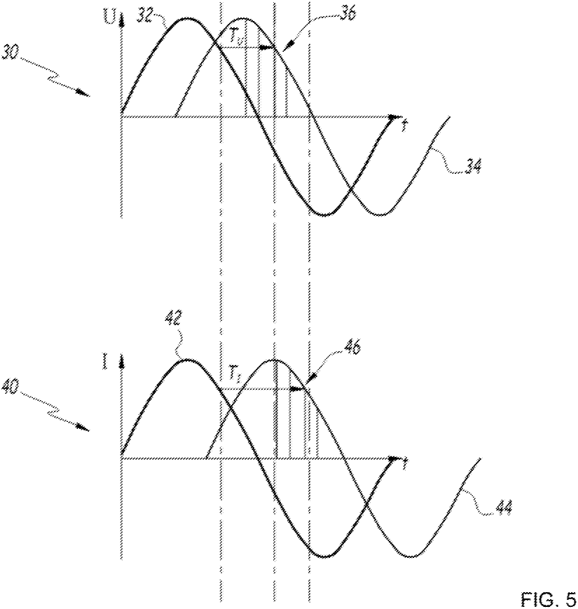

In FIG. 5, this gap is not visible and has already been corrected, the two curves having the same timeline.

These drift and gap values are calculated in step 76, which is preferably repeated periodically.

In parallel with these steps, in a step 71, the current measurement module 6 measures (samples) the current value. This measurement is for example repeated multiple times periodically, for example using the second sampling frequency.

Each current measurement is then timestamped in a step 73 by the current measurement module 6 using the local clock thereof, taking into account the correction values determined in step 76. The measured values and the corresponding timestamp data may then be stored in a step 75.

In other words, each time the module 6 samples an electrical current value using the measurement element 20, the measurement module 6 determines a corresponding local timestamp datum for each current measurement (for each sampling), said timestamp being provided taking into account the correction values determined in step 76. This allows the instant of the current measurement to be dated in a corrected time reference frame that corresponds to the time reference frame of the main module 4 (or at least comes as close as possible thereto), and in which the time offset between the modules 4 and 6 is automatically compensated for.

Preferably, the corrected timestamp is provided by calculating an estimated time (termed “EstimatedMasterTime”) using the following formula:

$$\begin{matrix}E s t i m a t e d M a s t e r T i m e \left(L o c a l T i m e\right) \\ = O f f s e t + S l o p e \times \left(L o c a l T i m e - L a s t S y n c L o c a l T i m e\right)\end{matrix}$$

where:

“offset” and “slope” are the correction values calculated prior to step 76, “LocalTime” denotes the uncorrected local timestamp value (that is to say the instant measured using the local clock, akin to what is done in step 70) and “LastSyncLocalTime” denotes the instant at which the message was received by the current measurement module 6, said instant being measured (timestamped) by the current measurement module 6 in the time reference frame thereof.

Other calculation formulae may be used.

For example, the calculation of the estimated time is repeated, the successive current measurements taken then being timestamped using this estimated time, until the next update. As a variant, the estimated time may be recalculated for each current measurement.

An advantage of these embodiments is that, as the correction values are calculated periodically, the local timestamps provided for the current measurements are updated periodically, for example in each cycle, allowing automatic compensation for any drifts that might occur during the operation of each current measurement module 6, such as a clock drift.

As a variant, each current measurement could be timestamped in step 73 by the current measurement module 6 using the local clock thereof, as described hereinabove. Next, the corrected timestamp datum could be calculated separately, secondly, for each current measurement, on the basis of the local timestamp datum and taking into account the correction values determined in step 76.

In parallel with these steps based on timestamps, in many embodiments, the method advantageously implements steps of correcting the measured current and voltage values on the basis of the already known calibration data (for example which are stored in memory).

FIG. 5 shows an example illustrating an aspect of the sampling of the current and voltage values by the measurement modules 4 and 6.

The graph 30 includes a first curve 32 representing the trend in the actual voltage (labelled U, on the ordinate) in a location of the electrical installation over time (labelled t, on the abscissa).

The second curve 34 represents the trend in the measured voltage reconstructed on the basis of the values sampled by the voltage sensor over time.

The reference 36 denotes a measurement point provided by way of example to illustrate the existence of a delay, labelled “Tu”, between the moment at which the actual voltage takes a certain value and the moment for which the corresponding sampling is finished.

In practice, this first delay Tu corresponds to the period required by the processing circuit 12 to process the signal measured by the measurement element 10. This delay is generally fixed for a given frequency; it is a feature of the measurement chain of the voltage measurement module 4, and depends for example on the properties of the measurement element 10, the analogue-to-digital converter and the processor that are present in the processing circuit 12, and also of the digital filters implemented by the processor, among other things.

Staying with FIG. 5, the graph 40 includes a first curve 42 representing the trend in the actual current (labelled I, on the ordinate) in a location of the electrical installation over time (labelled t, on the abscissa).

The second curve 44 represents the trend in the measured current reconstructed on the basis of the values sampled by the current sensor 6 over time.

The reference 46 denotes a measurement point provided by way of example to illustrate the existence of a delay, labelled “Tₗ” between the moment at which the “actual” current takes a certain value and the moment for which the corresponding sampling is finished.

In practice, this second delay Tₗ corresponds to the period required by the processing circuit 22 to process the signal measured by the measurement element 20. This delay is generally fixed for a given frequency; it is a feature of the measurement chain of the current measurement module 6, and depends for example on the properties of the measurement element 20, the analogue-to-digital converter and the processor that are present in the processing circuit 22, among other things.

A second aspect of the invention is therefore aimed at correcting or compensating for at least some of these delays, courtesy of a calibration carried out initially, in particular in order to automatically compensate for the difference between the second delay Tₗ and the first delay Tu.

For example, the time compensation is aimed at compensating for the fixed delays present in the measurement chains of the measurement modules 4 and 6, and is aimed especially at compensating for a fixed overall delay that is equivalent to the sum of the difference between a delay of the measurement module 4 and a delay of the measurement module 6 (these delays being intrinsic to the measurement electronics of the modules 4 and 6), with the difference between the time offset of the measurement module 4 and the time offset of the measurement module 6 (these offsets being the result of the process described in FIG. 3, which inadvertently generates delays due to the implementation of the timestamps and/or the sendings of messages).

For example, the time compensation (calibration time) is representative of an overall delay provided by the following formula:

$$\begin{matrix}C a l i b r a t i o n t i m e = T u - T i + \\ T i m e S y n c O f f s e t \_ U - T i m e S y n c O f f s e t \_ I\end{matrix}$$

where Tu is the delay of the measurement module 4 and Tᵢ is the delay of the measurement module 6, as are defined with reference to FIG. 5, “TimeSyncOffset _U” is the time offset of the measurement module 4 and “TimeSyncOffset _l” is the time offset of the measurement module 6.

For example, the time correction is applied by increasing or decreasing the time provided by the clock of the module 4 or 6 by the predefined calibration value from the calibration.

This correction is for example made by the measurement module 4. However, as a variant, this correction may be made after the message has been sent. The correction may be made in centralized fashion before the electrical quantity is calculated, in particular if this calculation is performed by an entity of the system 2 that is distinct from the measurement modules 4 and 6.

Moreover, the measured current values are automatically corrected by taking into account a time correction value previously stored in memory, said time correction value being from a preliminary calibration method.

For example, the measured current values are re-sampled so that the current values are “realigned” a posteriori on the same timescale as the measured voltage values. This allows, during a later calculation, the voltage and current values to appear a posteriori as having been measured simultaneously or quasi-simultaneously, even though the measurements have been taken by distinct measurement modules each having their own clock, these clocks not being actively synchronized.

In practice, the number of current samples may be modified so that the number thereof corresponds to the number of voltage values contained in each message.

In practice, each message may include the same number of voltage values measured for each cycle (for example 40 voltage samples per message).

This correction is made for example by the measurement module 6, but here again the correction may be made differently, for example a posteriori in centralized fashion.

Finally, at the end of the method, for example once the voltage and current values have been acquired by the measurement modules 4 and 6 (and corrected using the calibration data), at least one value of the electrical quantity (such as electrical power) is calculated on the basis of the successive current and voltage values from the measurement modules 4 and 6. In other variants, the electrical quantity is calculated in real time, as the current values are being measured by the measurement modules 6 and the measured voltage values are being received by the measurement modules 6.

For example, in order to calculate an electrical power, each measured voltage value is multiplied by the corresponding current value estimated (by interpolation) at the same instant. The operation is repeated in order to calculate and obtain a succession of values representing the trend in the electrical power over time.

It will therefore be understood that said electrical quantity is calculated by taking into account (at least implicitly) the delay correction values calculated for each sensor for each of the measurements. The calculation of said electrical quantity also takes into account (at least implicitly) the calibration corrections made to the measured current and voltage values. Optionally, other corrections may be made on this occasion, for example in order to adjust the time compensation according to other parameters, such as the frequency of the measured signal.

Owing to the invention, timestamping the current and voltage measurements and taking into account the intrinsic delay peculiar to the measurement chain of each sensor allow the delay after the measurement has been taken to be corrected.

In other words, instead of synchronizing the clocks of the current and voltage measurement modules so that they measure the voltage and the current at the same time, it is the voltage and current signals measured by the sensors that are synchronized virtually, by correcting the time reference frame of the current measurement modules.

It is thus possible to determine electrical quantities, in particular electrical quantities calculated on the basis of the measurements taken by the measurement modules, such as an electrical power, easily and reliably.

Moreover, using the current and voltage calibration values advantageously allows compensation for the fixed delays due to the measurement chain of the different measurement modules 4 and 6 (delays that are generally constant over time for a given frequency, these delays and/or these phase shifts originating from elements such as the analogue-to-digital converter, an analogue anti-aliasing filter and the digital filters implemented in the processor, for example).

Optionally, the measured voltage values may also be corrected in analogue fashion, for example before they are sent in said message, by taking into account a time correction value previously stored in memory, said time correction value being from a preliminary calibration method.

For example, the voltage values measured in a measurement cycle are re-sampled, for example so that each measurement cycle (and, where appropriate, each message sent) includes the same number of measured voltage values (for example 40 voltage samples per measurement cycle). For this resampling, a corrected timebase that includes a time compensation from the calibration method is used.

Such calibration of the voltage values nevertheless remains optional and may be omitted. Just as for the calibration of the current values, described hereinabove, it is possible to adjust the time compensation according to the frequency of the measured signal.

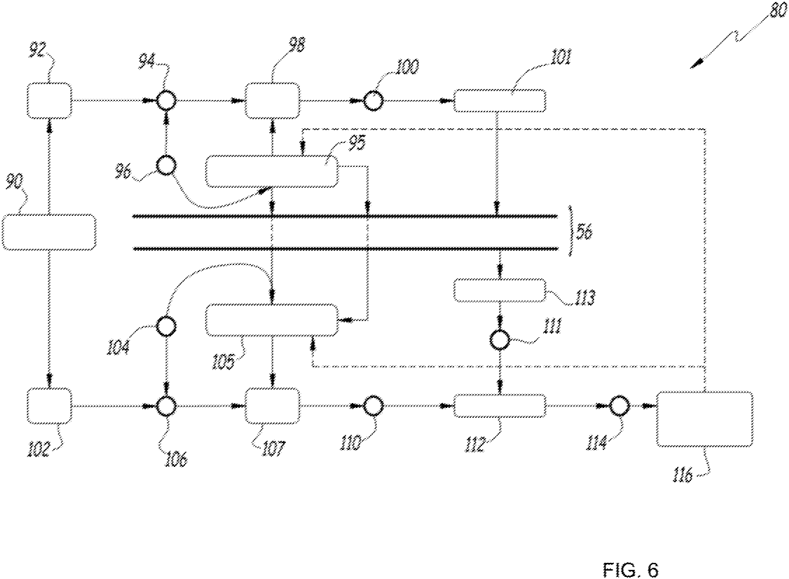

FIG. 6 describes an example of a calibration method implemented in order to initially calibrate the measurement modules 4 and 6 of the system 2 so as to calculate the current and voltage calibration values used in the method described hereinabove.

Said calibration method is illustrated here in conjunction with the voltage and current measurement steps described hereinabove.

This calibration method is preferably carried out in the factory before the system 2 is started up. However, optionally but nevertheless advantageously, the calibration method may be implemented after the system 2 has been started up, for example by repeating the calibration at regular intervals (every year, for example).

The diagram 80 in FIG. 6 shows steps implemented by at least one voltage measurement module 4 (upper half of the diagram) and by one of the current measurement modules 6 (lower half of the diagram) in a test phase, which is distinct from the operating phase. The steps are, for example, implemented by the respective processors of the voltage measurement module 4 and of the current measurement modules 6.

Here again, the steps of the method that will be described could be executed in a different order. Some steps could be omitted. The example described does not prevent, in other embodiments, other steps from being implemented together and/or sequentially with the steps described.

The calibration is carried out by injecting alternating current and voltage signals for which the phase shift is known. The signals may come from a signal generator within a test installation fed by the signal generator. They may also be actual signals in an installation in the process of operating.

In block 90, the test signals are transmitted.

In a periodically repeated step (block 92), the voltage measurement module 4 acquires a voltage value by sampling the test signal.

In block 94, the measured voltage value is timestamped using the clock of the module 4, for example using a timestamp datum provided by the clock of the module 4 (block 96).

In block 98, the timestamp data associated with the measured voltage values are corrected using a correction datum provided by a first synchronization module of the measurement module 4 (block 95).

This allows movement into an ideal main time reference frame.

The synchronization module is here set up to implement the synchronization management functions described with reference to FIGS. 2, 3 and 4, for example to manage synchronization signals and to manage time correction parameters.

For example, the first calibration module 95 transmits a synchronization signal and the corresponding instant is timestamped courtesy of the clock of the module 4 (block 96). At this stage, the corresponding main timestamp datum contains the so-called synchronization delay (TimeSyncOffset _U) associated with the module 4.

In the example illustrated, the synchronization signal is sent on the communication link 56 to the module 6 in the form of a message including the main timestamp datum (or the one measured for the previous synchronization signal).

The correction datum provided to block 98 allows the voltage samples to be timestamped using corrected timestamp information (block 100). In practice, the corrected timestamp data may, in spite of everything, contain a generic delay that is expected for all voltage measurement modules.

Here, block 96 corresponds to the local clock that provides the local timestamp data of the module 6.

These timestamp data are then sent to the module 6.

For example, in block 101, the module 4 sends a message on the communication link 56 to the module 6, said message including the timestamped voltage samples.

In parallel, for the current measurement module 6, in a periodically repeated step (block 102), the measurement module 6 acquires a current value by sampling the test signal received.

In block 106, the measured current value is timestamped using the clock of the module 6, for example using a timestamp datum provided by the clock of the module 6 (block 104).

In block 107, the timestamp data provided by the clock of the module 6 are corrected using a correction datum provided by a calibration module of the measurement module 6 (block 105).

For example, the calibration module 105 initiates a cycle on reception of the synchronization signal sent by the module 4. The corresponding instant is timestamped courtesy of the clock of the module 6 (block 104). At this stage, the corresponding local timestamp datum contains the so-called synchronization delay (TimeSyncOffset _l) associated with the module 6.

The module 105 determines an estimated time value on the basis of the local timestamp and the main timestamp datum received in the message, analogously to what has been described hereinabove with reference to the method in FIG. 3.

Said datum, provided in block 107, allows the current samples to be timestamped using corrected timestamp information (block 110), but said information nevertheless includes the delay Tₗ at this stage. Since the estimated time contains the delays originating from the voltage measurement module 4 and also the delays introduced by the module 6 during timestamping, the timestamp data are marred by the overall delay defined hereinabove (Calibration Time). It should be noted that, in general, the absolute values of these delays will not be known, but it will be ensured that they are identical in all measurement modules, and that the time differences between the current and voltage values are zero.

In parallel, in block 113, the module 6 receives the voltage samples contained in the received message. The timestamp data are extracted (block 111) and, in block 112, the measured current values are re-sampled in order to make the timing thereof correspond to that of the measured voltage values that have been received from the module 4 (that is to say so that the measured current values are time-realigned with the voltage values). Next, the phase shift between the measured current and voltage is determined, and this phase is compared with the known phase shift between the input signals in order to determine the overall delay of the measurement chain. This allows voltage or current correction data (according to whether a voltage or current reference measurement module has been used) to be determined. The correction data are then provided (by a calculation module illustrated in block 116) to the calibration module 95 and to the calibration module 105. It is also these correction data that are used in the method in FIG. 3.

For example, in order to determine the phase shift between the voltage and current signals, in block 114, the active power and reactive power values are calculated on the basis of the measured voltage and current values. Other methods are nevertheless possible in order to determine the phase shift between the voltage and current signals.

Then, in block 116, a time correction value is calculated for the measurement modules 4 and 6 on the basis of the calculated active power and reactive power values.

For example, the time correction value (UCalibTimeCorrection) for the voltage measurement module 4 is calculated using the following formula:

$$U C a l i b T i m e C o r r e c t i o n = \frac{A r c t a n \left(\frac{Q}{P}\right) - C a l i b r a t i o n T a r g e t}{360 \times F r e q u e n c y}$$

where “Q” and “P” are, respectively, the (average) reactive power and active power calculated hereinabove, “CalibrationTarget” is the value of the phase shift between the voltage input signal and the current input signal and “Frequency” is the oscillation frequency of the test signals.

For example, the time correction value (ICalibTimeCorrection) for the voltage measurement module 4 is calculated in the same way.

This value is then provided to the modules 95 and 105 in order to shift the time of the signal measured by at least one of the respective modules 4 and 6. For example, the time provided by the clock of the module 4 or 6 is increased or decreased by this amount UCalibTimeCorrection or ICalibTimeCorrection.

Preferably, the voltage 4 and current 6 measurement modules are calibrated separately. For example, when the voltage measurement module 4 is calibrated, the current measurement module 6 used is a reference measurement module, which, although it has an intrinsic delay, is ideally devoid of additional delays or of drift. The same goes for when a current measurement module 6 is calibrated, by taking a reference voltage measurement module 4.

It is understood that, in order to calculate the time correction value, the calibration method uses the method for determining an electrical quantity as described hereinabove with reference to FIGS. 2 to 5 in particular. This allows the calibration method to correct the time faults (in particular the time difference) and to be independent of the communication link used.

Optionally, the calibration method may also allow the clock of the module 4 to be corrected so that it corresponds or comes as close as possible to an ideal clock. This allows the measurement of the frequency of the voltage to be improved.

For example, the calibration value of the drift (CalibrationDrift) is provided by the following formula:

$$C a l i b r a t i o n D r i f t = \frac{F r e q u e n c y - F r e q u e n c y T a r g e t}{F r e q u e n c y T a r g e t}$$

where “Frequency” is the oscillation frequency of the test signals and “FrequencyTarget” is a target frequency, for example the frequency of the measurement cycles.

The embodiments and the variants contemplated above may be combined with one another to produce new embodiments.

1. A method for determining an electrical quantity in an electrical installation, using a measurement system including at least one voltage measurement module and at least one current measurement module, which are coupled to the electrical installation, each of said measurement modules including a sensor, a processor, a memory and a clock, the method involving:
by way of the voltage measurement module:
periodically measuring a voltage in the electrical installation,
periodically sending a synchronization signal to at least one of the current measurement modules,
sending to said current measurement module a message including at least one main timestamp datum indicating the instant at which the voltage measurement module has transmitted the synchronization signal, said instant being measured by the voltage measurement module using the clock thereof,
sending to said current measurement module(s) a message including at least one measured voltage value,
by way of a current sensor measurement module:
periodically measuring an electrical current in the electrical installation,
on receiving the synchronization signal sent by the voltage measurement module, calculating, using the clock of said current measurement module, a local timestamp datum indicating the instant at which the current measurement module has received said synchronization signal,
determining successive delay correction values on the basis of the main timestamp datum received and the local timestamp datum calculated for each synchronization signal received from the voltage measurement module, the successive current measurements taken by the current measurement module being timestamped by the current measurement module, using the clock thereof, taking into account the delay correction values thus determined,
by way of a processor, calculating at least one value of an electrical quantity on the basis of the successive current and voltage values from the measurement modules.

2. The method according to claim 1, wherein the delay correction applied to the timestamp data associated with the measured current values is calculated according to the difference between the main timestamp datum received and the local timestamp datum calculated for one and the same synchronization signal.

3. The method according to claim 1, wherein the calculation of said electrical quantity includes first interpolating the current values for the instants corresponding to the instants for which the voltage values have been measured by the voltage measurement module, said interpolation being performed on the basis of the measured current values and the timestamp data associated with the measured current values.

4. The method according to claim 1, wherein a drift of the current measurement module is estimated on the basis of the ratio between, on the one hand, the time interval between two consecutive sendings of the synchronization signal by the voltage measurement module , said time interval being determined on the basis of the main timestamp data, and, on the other hand, the time interval between reception of two synchronization signals received consecutively by the current measurement module , said time interval being determined on the basis of the local timestamp data.

5. The method according to claim 1, wherein each voltage measurement by the voltage measurement module is timestamped by the voltage measurement module, the corresponding timestamp datum being sent by the voltage measurement module including, for each measured voltage value.

6. The method according to claim 1, wherein the timestamp data associated with the measured voltage values are automatically corrected, before being sent in said message, taking into account a time correction value previously stored in memory, said time correction value being from a preliminary calibration method.

7. The method according to claim 1, wherein the timestamp data associated with the measured current values are automatically corrected taking into account a time correction value previously stored in memory, said time correction value being from a preliminary calibration method.

8. The method according to claim 6 , wherein, to calculate the time correction value, the calibration method involves a method for determining an electrical quantity in accordance with any one of the preceding claims .

9. The method according to claim 1, wherein the measurement modules of the system are in communication via a wireless communication link, the message sent by the voltage measurement module being a radio message.

10. The method according to claim 1, wherein the measurement modules of the system are in communication via a wired communication link, such as a data bus.

11. The method according to claim 1, wherein the electrical quantity is calculated by an electronic processing circuit of at least one of the current measurement modules.

12. The method according to claim 1, wherein the calculated electrical quantity is an electrical power calculated on the basis of the current and voltage values measured by the measurement modules.

13. A system for determining an electrical quantity in an electrical installation, said system including at least one voltage measurement module and at least one current measurement module, which are coupled to the electrical installation, each of said measurement modules including a sensor, a processor, a memory and a clock, the system being set up to implement a method for determining an electrical quantity, the method involving:
by way of the voltage measurement module (4):
periodically measuring a voltage in the electrical installation,
periodically sending a synchronization signal to at least one of the current measurement modules,
sending to said current measurement module a message including at least one main timestamp datum indicating the instant at which the voltage measurement module has transmitted the synchronization signal, said instant being measured by the voltage measurement module using the clock thereof,
sending to said current measurement module(s) a message including at least one measured voltage value,
by way of a current sensor measurement module:
periodically measuring an electrical current in the electrical installation,
on receiving the synchronization signal sent by the voltage measurement module, calculating, using the clock of said current measurement module, a local timestamp datum indicating the instant at which the current measurement module has received said synchronization signal,
determining successive delay correction values on the basis of the main timestamp datum received and the local timestamp datum calculated for each synchronization signal received from the voltage measurement module, the successive current measurements taken by the current measurement module being timestamped by the current measurement module, using the clock thereof, taking into account the delay correction values thus determined,
by way of a processor, calculating at least one value of an electrical quantity on the basis of the successive current and voltage values from the measurement modules.
